(19) United States
(12) Patent Application Publication
(10) Pub. No.: US 2026/0107491 A1
(43) Pub. Date: Apr. 16, 2026

(54) SEMICONDUCTOR STRUCTURES

(71) Applicant: Industrial Technology Research Institute, Hsinchu (TW)

(72) Inventors: Po-Tsung Tu, Tainan City (TW); Hsiang-Chun Wang, Taichung City (TW); Jui-Chin Chen, Hsinchu County (TW); Chang-Yan Hsieh, Yilan County (TW); Hui-Yu Chen, Taichung City (TW); De Shieh, Kaohsiung City (TW); Po-Chun Yeh, Taichung City (TW); Po-Tsung Lee, Hsinchu City (TW); Hao-Chung Kuo, Hsinchu City (TW)

(73) Assignee: Industrial Technology Research Institute, Hsinchu (TW)

(21) Appl. No.: 19/017,810

(22) Filed: Jan. 13, 2025

(30) Foreign Application Priority Data
Oct. 14, 2024 (TW) 113138937

(51) Int. Cl. H10D 30/47; H10D 30/01; H10D 62/824; H10D 84/01; H10D 84/82

(52) U.S. Cl. CPC H10D 30/475; H10D 30/476; H10D 62/824; H10D 84/82; H10D 30/015; H10D 84/0123

(57) ABSTRACT

A semiconductor structure includes a first semiconductor layer, a second semiconductor layer, multiple third semiconductor structures, a conductive layer, and an insulating layer. The first semiconductor layer is disposed over a substrate. The second semiconductor layer is disposed on the first semiconductor layer. The third semiconductor structures are disposed on the second semiconductor layer. The conductive layer is disposed over the third semiconductor structures. The insulating layer is disposed between the conductive layer and the third semiconductor structures to electrically isolate the conductive layer from the third semiconductor structures. A two-dimensional electron gas channel is formed in a portion of the first semiconductor layer, the portion of the first semiconductor layer is not overlapped with the third semiconductor structures in a vertical direction, and the two-dimensional electron gas channel is located near an interface between the first semiconductor layer and the second semiconductor layer.

### CROSS-REFERENCE TO RELATED APPLICATION

This application claims the priority benefit of Taiwan application serial no. 113138937, filed on Oct. 14, 2024. The entirety of the above-mentioned patent application is hereby incorporated by reference herein and made a part of this specification.

### TECHNICAL FIELD

The disclosure relates to a semiconductor structure.

### BACKGROUND

Recently, since a high electron mobility transistor (HEMT) has advantages of high frequency, high power density, and high operating temperature, it is often used in microwave electronic components and power electronic components. As electronic products develop towards being lighter, thinner, and smaller, electronic components is also required to be miniaturized in response to demands, and a fin field-effect transistor (FinFET) structure has been developed to reduce an impact of short-channel effects on components. Generally speaking, the enhanced high electron mobility transistor is difficult to be implemented. The enhanced high electron mobility transistor may only be implemented when a width of a fin is less than 100 nm. A manufacturing process thereof is complex, the cost is high, and a threshold voltage corresponding to the obtained component will be too low, affecting performance of the components.

### SUMMARY

Some embodiment of the disclosure provide semiconductor structures. A semiconductor structure in the disclosure includes a first semiconductor layer, a second semiconductor layer, multiple third semiconductor structures, a conductive layer, and an insulating layer. The first semiconductor layer is dispsoed over a substrate. The second semiconductor layer is disposed on the first semiconductor layer. The third semiconductor structures are disposed on the second semiconductor layer. The conductive layer is disposed on the third structure semiconductors. The insulating layer is disposed between the conductive layer and the third semiconductor structures to electrically isolate the conductive layer from the third semiconductor structures. A two-dimensional electron gas channel is formed in a portion of the first semiconductor layer. The portion of the first semiconductor layer is not overlapped with the third semiconductor structures in a vertical direction. The two-dimensional electron gas channel is located near an interface between the first semiconductor layer and the second semiconductor layer. The vertical direction is parallel to a normal direction of a top surface of the substrate.

Another semiconductor structure in the disclosure includes a first transistor. The first transistor includes a first fin structure, a third semiconductor layer, and a first gate. The first fin structure is disposed over a substrate. The first fin structure further includes a first semiconductor layer and a second semiconductor layer. The second semiconductor layer is disposed on the first semiconductor layer. A sidewall of the first semiconductor layer is flush with a sidewall of the second semiconductor layer. The third semiconductor layer is disposed on a top surface and a sidewall of the first fin structure. The first gate is disposed on the third semiconductor layer. A two-dimensional electron gas channel is formed in the first semiconductor layer of the first fin structure, and is located near an interface between the first semiconductor layer and the second semiconductor layer.

### BRIEF DESCRIPTION OF THE DRAWINGS

FIG. 1A is a schematic three-dimensional diagram of a semiconductor structure according to an embodiment of the disclosure.

FIG. 1B is a schematic cross-sectional diagram of a semiconductor structure according to an embodiment of the disclosure.

FIG. 2 is a schematic cross-sectional diagram of a semiconductor structure according to an embodiment of the disclosure.

FIG. 3A is a schematic three-dimensional diagram of a semiconductor structure according to an embodiment of the disclosure.

FIG. 3B is a schematic cross-sectional diagram of a semiconductor structure according to an embodiment of the disclosure.

FIGS. 4, 5A and 5B, 6A and 6B, 7A and 7B, 8, 9, 10A and 10B, 11A and 11B to 12A and 12B are schematic diagrams of a manufacturing process of a semiconductor structure according to an embodiment of the disclosure.

FIG. 13A is a schematic three-dimensional diagram of a semiconductor structure according to an embodiment of the disclosure.

FIG. 13B is a schematic cross-sectional diagram of an embodiment cut along a sectional line K-K′ in FIG. 13A.

FIG. 13C is a schematic cross-sectional diagram of an embodiment cut along a sectional line L-L′ in FIG. 13A.

FIG. 13D is a schematic circuit diagram of a semiconductor structure according to an embodiment of the disclosure.

FIGS. 14A and 14B, 15, and 16A and 16B are schematic diagrams of a manufacturing process of a semiconductor structure according to an embodiment of the disclosure.

### DETAILED DESCRIPTION OF DISCLOSED EMBODIMENTS

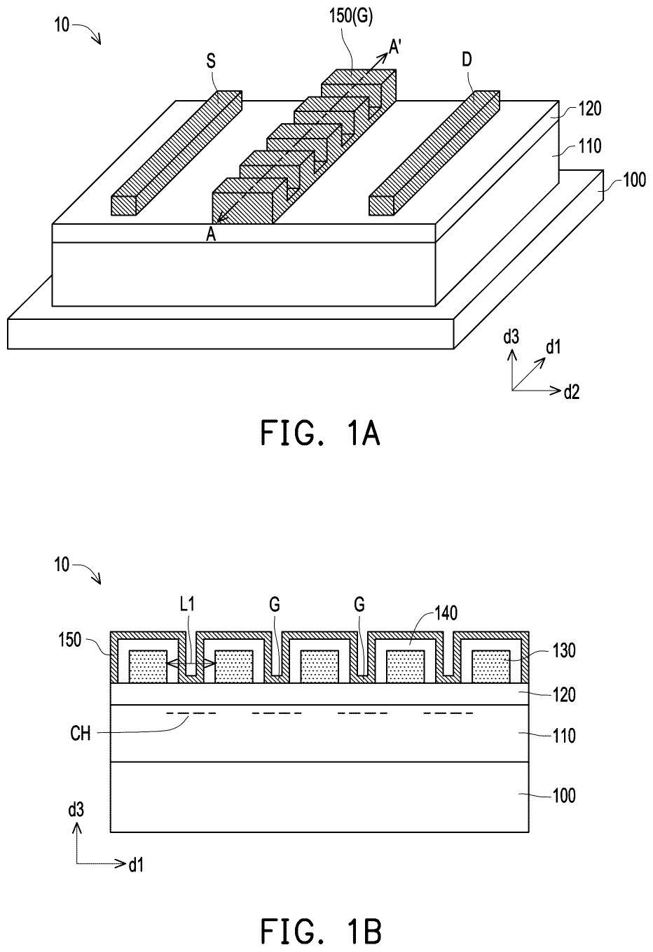

FIG. 1A is a schematic three-dimensional diagram of a semiconductor structure 10 according to an embodiment of the disclosure. FIG. 1B is a schematic cross-sectional diagram of the semiconductor structure 10 according to an embodiment of the disclosure. FIG. 1B may be regarded as a schematic cross-sectional diagram of an embodiment cut along a sectional line A-A′ in FIG. 1A.

Referring to FIGS. 1A and 1B, the semiconductor structure 10 includes a substrate 100, a first semiconductor layer 110, a second semiconductor layer 120, multiple third semiconductor structures 130, an insulating layer 140, and a conductive layer 150. The first semiconductor layer 110 is disposed on the substrate 100. The second semiconductor layer 120 is disposed on the first semiconductor layer 110. The third semiconductor structures 130 are disposed on the second semiconductor layer 120. The conductive layer 150 is disposed on the third structure semiconductors 130. The insulating layer 140 is disposed between the conductive layer 150 and the third semiconductor structures 130 to electrically isolate the conductive layer 150 from the third semiconductor structures 130.

In some embodiments, the substrate 100 is a semiconductor substrate. The substrate 100 may include a silicon substrate, a silicon carbide substrate, a sapphire substrate, a silicon-on-insulator substrate, or other suitable semiconductor substrates, but the disclosure is not limited thereto.

In some embodiments, the first semiconductor layer 110 and the second semiconductor layer 120 are semiconductor materials with different energy bands, so that a heterostructure interface is formed between the first semiconductor layer 110 and the second semiconductor layer 120, and two-dimensional electron gas may be generated near the heterostructure interface. In some embodiments, both the first semiconductor layer 110 and the second semiconductor layer 120 are undoped semiconductor materials. In some embodiments, the first semiconductor layer 110 may include gallium nitride (GaN), and the second semiconductor layer 120 may include aluminum gallium nitride (AlGaN). However, the disclosure is not limited thereto. In some embodiments, the first semiconductor layer 110 and the second semiconductor layer 120 may be sequentially formed on the substrate 100 through an epitaxial process or other growth processes.

In some embodiments, the third semiconductor structures 130 are arranged in a first direction d1, and adjacent two of the third semiconductor structures 130 are separated from each other. The third semiconductor structures 130 may be in direct contact with the second semiconductor layer 120. In some embodiments, the third semiconductor structures 130 may include p-type gallium nitride, which is gallium nitride doped with p-type dopants. In some embodiments, the p-type dopant may include boron, magnesium, beryllium, or other suitable p-type dopants, but the disclosure is not limited thereto. In some embodiments, the third semiconductor structures 130 may be formed through the epitaxial process or other growth processes. For example, a patterned mask layer may be formed on the second semiconductor layer 120 first to expose a portion of the second semiconductor layer 120, and then the third semiconductor structures 130 may be formed on the exposed second semiconductor layer 120 through the epitaxial process or other growth processes, and the patterned mask layer is removed.

In some embodiments, the insulating layer 140 may cover a top surface and a sidewall of each of the third semiconductor structures 130. In some embodiments, a material of the insulating layer 140 may include silicon oxide, silicon oxynitride, or other suitable insulating materials, but the disclosure is not limited thereto. In some embodiments, the insulating layer 140 may be formed through a chemical vapor deposition process, a physical vapor deposition process, a thermal oxidation process, or other suitable processes.

In some embodiments, a thickness of the insulating layer 140 may be between 10 nm and 500 nm to electrically isolate the third semiconductor structures 130 from the conductive layer 150 effectively.

In some embodiments, the adjacent insulating layer 140 covering the adjacent third semiconductor structures 130 are not connected to each other. In other words, the insulating layer 140 has multiple openings (not marked) to expose the second semiconductor layer 120 corresponding to the adjacent third semiconductor structures 130.

In some embodiments, the conductive layer 150 may be conformally formed on the insulating layer 140. In some embodiments, the conductive layer 150 may further extend onto the second semiconductor layer 120, and the conductive layer 150 may be in direct contact with the second semiconductor layer 120, which is the conductive layer 150 may be filled in the aforementioned openings of the insulating layer 140. In some embodiments, the conductive layer 150 may be a single-layer or multi-layer structure, but the disclosure is not limited thereto. In some embodiments, a material of the conductive layer 150 may include gold, aluminum, copper, nickel, titanium, an alloy thereof, a combination thereof, or other suitable metal materials. In some embodiments, the conductive layer 150 may be formed through the chemical vapor deposition process, the physical vapor deposition process, evaporation, or other suitable processes.

In some embodiments, the conductive layer 150 may include multiple gates G. The gates G are located between adjacent two of the third semiconductor structures 130, and the gate G may be in direct contact with the second semiconductor layer 120. In other words, the gate G and the third semiconductor structures 130 are arranged on the second semiconductor layer 120 in a staggered manner in the first direction d1. In some embodiments, the gates G are controlled by the same electrode (i.e., the conductive layer 150).

In some embodiments, the first semiconductor layer 110 may further include two-dimensional electron gas channels CH. More specifically, the two-dimensional electron gas channels CH may be located in the first semiconductor layer 110 corresponding to the gates G, and the two-dimensional electron gas channels CH are located near an interface between the first semiconductor layer 110 and the second semiconductor layer 120. In other words, the two-dimensional electron gas channels CH may be formed in a portion of the first semiconductor layer 110, and the portion of the first semiconductor layer 110 is not overlapped with the third semiconductor structure 130 in a third direction d3 (also called a vertical direction). The third direction d3 is parallel to a normal direction of a top surface of the substrate 100. In some embodiments, the third direction d3 is perpendicular to the first direction d1. The first direction d1 is parallel to the top surface of the substrate 100. In the disclosure, the two-dimensional electron gas channels CH may refer to a channel through which the two-dimensional electron gas mainly passes. More specifically, the two-dimensional electron gas channels CH may be multiple channels corresponding to the gates G.

Since the third semiconductor structure 130 is disposed on the second semiconductor layer 120 and is in direct contact with the second semiconductor layer 120, a bandgap between the corresponding first semiconductor layer 110 and second semiconductor layer 120 is increased, raising the conduction band above Femi level, which causes depletion of the two-dimensional electron gas in the first semiconductor layer 110 corresponding to the third semiconductor structure 130, and since the third semiconductor structure 130 is electrically isolated from the conductive layer 150 through the insulating layer 140, it is difficult to drive the two-dimensional electron gas in the first semiconductor layer 110 corresponding to the third semiconductor structure 130 through the conductive layer 150. In this way, the third semiconductor structure 130 and the insulating layer 140 disposed on the second semiconductor layer 120 may isolate the two-dimensional electron gas channels CH to form a non-channel region, thereby achieving an effect similar to isolation between adjacent fins through grooves in fin field-effect transistors through a relatively simple process.

In some embodiments, the semiconductor structure 10 further includes a source S and a drain D. The source S and the drain D extend in the first direction d1, and are respectively disposed on two opposite sides of the conductive layer 150 (not shown in the drawing, for example, the source S and the drain D may be respectively disposed on left and right sides in FIG. 1A), so that the conductive layer 150 is located between the source S and the drain D, and the conductive layer 150 is arranged parallel to the source S and the drain D.

In some embodiments, the semiconductor structure 10 may be a high electron mobility transistor. In some embodiments, when a distance L1 between the adjacent third semiconductor structures 130 (equivalent to a width of the single two-dimensional electron gas channel CH) is greater than 100 nm, and the semiconductor structure 10 may be implemented as a depletion-type high electron mobility transistor (HEMT). It is worth noting that when the distance L1 between the adjacent third semiconductor structures 130 is greater than 100 nm, the semiconductor structure 10 may be further implemented as an enhanced high electron mobility transistor to reduce occurrence of a short-channel effect. When the distance L1 between the adjacent third semiconductor structures 130 is less than or equal to 100 nm, the semiconductor structure 10 may be implemented as the enhanced high electron mobility transistor.

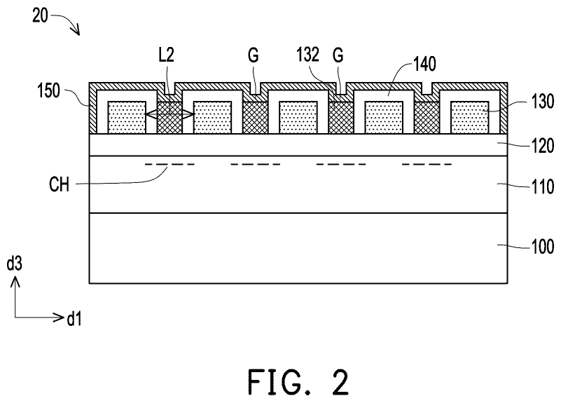

FIG. 2 is a schematic cross-sectional diagram of a semiconductor structure 20 according to an embodiment of the disclosure. A schematic three-dimensional diagram in FIG. 2 may be similar to that shown in FIG. 1A, and FIG. 2 may be a schematic cross-sectional diagram of another embodiment cut along the sectional line A-A′ in FIG. 1A. It is noted that some of the reference numerals and descriptions in FIGS. 1A and 1B will apply to FIG. 2. The same reference numerals will represent the same or similar components and the descriptions of the same technical contents will be omitted. Reference may be made to the above embodiment for the omitted descriptions, which will not be repeated in the following embodiment.

Referring to FIG. 2, the semiconductor structure 20 in this embodiment is different from the semiconductor structure 10 in FIG. 1B in that the semiconductor structure 20 may further include multiple fourth semiconductor structures 132, and the fourth semiconductor structures 132 are disposed on the second semiconductor layer 120 and are arranged with the third semiconductor structures 130 in a staggered manner. More specifically, the fourth semiconductor structures 132 may be arranged between two adjacent of the third semiconductor structures 130, and the third semiconductor structures 130 may be arranged between two adjacent of the fourth semiconductor structures 132, so that third semiconductor structures 130 and the fourth semiconductor structures 132 are arranged in a staggered manner. In some embodiments, the insulating layer 140 may be located between the adjacent third semiconductor structures 130 and fourth semiconductor structures 132 to electrically isolate the third semiconductor structures 130 from the fourth semiconductor structures 132.

In some embodiments, the third semiconductor structures 130 and the fourth semiconductor structures 132 may be formed by the same material. For example, the third semiconductor structures 130 and the fourth semiconductor structures 132 may both include the p-type gallium nitride. The third semiconductor structures 130 and the fourth semiconductor structures 132 may be formed in the same process steps, but the disclosure is not limited thereto.

In some embodiments, the conductive layer 150 may be further disposed on the fourth semiconductor structures 132, and the conductive layer 150 may be in direct contact with the fourth semiconductor structures 132. The two-dimensional electron gas channels CH are overlapped with the fourth semiconductor structures 132 in the third direction d3. Specifically, the gates G of the conductive layer 150 may be in direct contact with the fourth semiconductor structures 132. Since the fourth semiconductor structures 132 are disposed on the second semiconductor layer 120, and the fourth semiconductor structures 132 is in direct contact with the second semiconductor layer 120, the bandgap between the corresponding first semiconductor layer 110 and second semiconductor layer 120 is increased, raising the conduction band above the Fermi level, which causes the two-dimensional electron gas channels CH to remain in a depletion state without applying a bias voltage to the gates G. If the two-dimensional electron gas channels CH are about to be turned on, a threshold voltage of the gates G is required to be increased accordingly, so that the two-dimensional electron gas may pass through the two-dimensional electron gas channels CH. That is to say, by disposing the fourth semiconductor structures 132 between the gates G (or the conductive layer 150) and the second semiconductor layer 120, the threshold voltage of the gate G could be increased, so that the enhanced high electron mobility transistor may be easily implemented. In this embodiment, when a width L2 of the two-dimensional electron gas channels CH (or a distance between the adjacent third semiconductor structures 130) is greater than 100 nm, the semiconductor structure 20 may be implemented as the enhanced high electron mobility transistor, and the occurrence of the short-channel effect may be reduced.

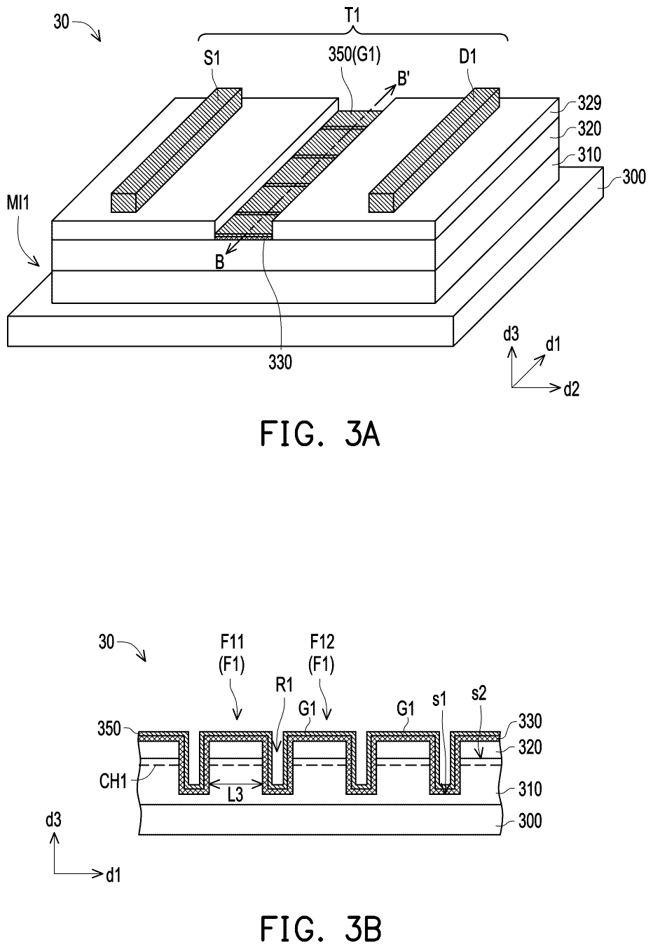

FIG. 3A is a schematic three-dimensional diagram of a semiconductor structure 30 according to an embodiment of the disclosure. FIG. 3B is a schematic cross-sectional diagram of the semiconductor structure 30 according to an embodiment of the disclosure. FIG. 3B is, for example, a schematic cross-sectional diagram of an embodiment cut along a sectional line B-B′ in FIG. 3A.

Referring to FIGS. 3A and 3B, in this embodiment, the semiconductor structure 30 includes a substrate 300, multiple fin structures F1, a third semiconductor layer 330, and a first conductive layer 350. The fin structures F1 are disposed on the substrate 300. The third semiconductor layer 330 is disposed on top surfaces and sidewalls of the fin structures F1. In some embodiments, the first conductive layer 350 is disposed on the third semiconductor layer 330. Materials of the substrate 300, the third semiconductor layer 330, and the first conductive layer 350 may be similar to those of the substrate 100, the third semiconductor structure 130, and the conductive layer 150.

More specifically, each of the fin structures F1 may include a first semiconductor layer 310 and a second semiconductor layer 320, and the second semiconductor layer 320 is disposed on the first semiconductor layer 310. A sidewall of the first semiconductor layer 310 is flush with a sidewall of the second semiconductor layer 320. Here, “flush” may refer to a process being performed under ideal conditions such that the sidewall of the first semiconductor layer 310 and the sidewall of the second semiconductor layer 320 are coplanar, or it may refer to the process being performed within a tolerance range of the process technology thereof (e.g., a tolerance of ±5%), so that the sidewall of the first semiconductor layer 310 and the sidewall of the second semiconductor layer 320 are slightly offset. In some embodiments, the sidewalls of the first semiconductor layer 310 and the sidewalls of the second semiconductor layer 320 may constitute sidewalls of the fin structures F1, and top surfaces of the second semiconductor layer 320 may constitute top surfaces of the fin structures F1. In some embodiments, materials of the first semiconductor layer 310 and the second semiconductor layer 320 may be similar to those of the first semiconductor layer 110 and the second semiconductor layer 120, but the disclosure is not limited thereto.

In some embodiments, the fin structures F1 may include a first fin structure F11 and a second fin structure F12. For example, the fin structures F1 may be arranged on the substrate 300 in the first direction d1. More specifically, the first fin structure F11 and the second fin structure F12 are arranged on the substrate 300 in a staggered manner in the first direction d1. In some embodiments, the first semiconductor layer 310 of the fin structures F1 may extend to the adjacent fin structures F1, so that bottoms of the first semiconductor layer 310 of the adjacent fin structures F1 are connected to each other. More specifically, the first semiconductor layer 310 in the first fin structure F11 may extend to the first semiconductor layer 310 in the adjacent second fin structure F12, so that the bottoms of the first semiconductor layers 310 of any adjacent two of the fin structures F1 are connected to each other. In some embodiments, surfaces s1 of the first semiconductor layer 310 between the adjacent fin structures F1 is lower than interfaces s2 between the first semiconductor layer 310 and the second semiconductor layer 320.

From another perspective, the first semiconductor layer 310 and the second semiconductor layer 320 are sequentially disposed on the substrate 300 from bottom to top, and multiple grooves R1 are formed in the first semiconductor layer 310 and the second semiconductor layer 320, thereby forming the fin structures F1. Bottom surfaces (i.e., the surfaces s1) of the grooves R1 are lower than the interfaces s2 between the first semiconductor layer 310 and the second semiconductor layer 320, so that any two adjacent of the fin structures F1 are separated.

In some embodiments, the third semiconductor layer 330 may further extend into the grooves R1 and be in direct contact with the surfaces s1 of the first semiconductor layer 310. For example, the third semiconductor layer 330 may extend from a top surface and a sidewall of the first fin structure F11 to a bottom surface of a groove R1, and then extend to a top surface and a sidewall of the second fin structure F12. That is, the third semiconductor layer 330 may be conformally disposed on the top surfaces and the sidewalls of the fin structures F1.

In some embodiments, the first conductive layer 350 may be further conformally disposed on the third semiconductor layer 330. The first conductive layer 350 may include multiple gates G1 (also called first gates). The gates G1 are located on the fin structures F1 and are in direct contact with the third semiconductor layer 330. Two-dimensional electron gas channels CH1 may be formed in the first semiconductor layer 310 of the fin structures F1 and are located near interfaces between the first semiconductor layer 310 and the second semiconductor layer 320.

In some embodiments, the semiconductor structure 30 further includes a source S1 (also called a first source) and a drain D1 (also called a first drain). The source S1 and the drain D1 extend in the first direction d1, and are respectively disposed on two opposite sides of the first conductive layer 350 in a second direction d2, so that the first conductive layer 350 is located between the source S1 and the drain D1, and the first conductive layer 350, the source S1, and the drain D1 are arranged in parallel. The first direction d1 and the second direction d2 are perpendicular to each other, and the first direction d1 and the second direction d2 are parallel to the top surface of the substrate 100.

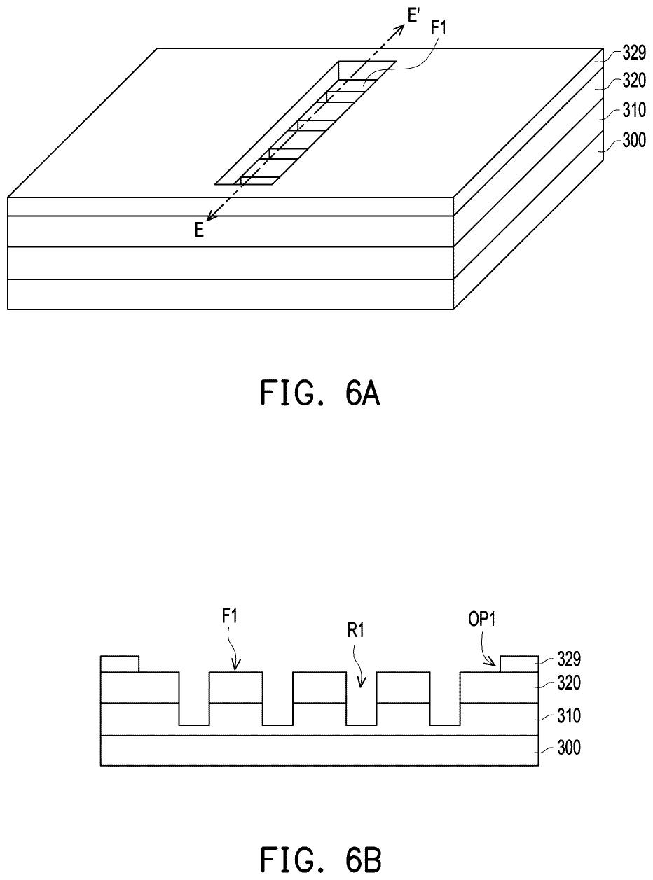

In some embodiments, the semiconductor structure 30 may further include a passivation layer 329 disposed on the second semiconductor layer 320. More specifically, the passivation layer 329 may have an opening (not marked, referring to an opening OP1 in FIG. 6B) to expose the fin structures F1. The third semiconductor layer 330 and the first conductive layer 350 may be located in the opening of the passivation layer 329 to cover the fin structures F1. In addition, the source S1 and the drain D1 may be disposed on the passivation layer 329 and extend through a portion of the passivation layer 329 to be in direct contact with the second conductive layer 320 located below the passivation layer 329. In some embodiments, the passivation layer 329 may include silicon oxide, silicon nitride, a combination thereof, or other suitable materials, but the disclosure is not limited thereto.

In some embodiments, the fin structures F1, the third semiconductor layer 330, the gates G1, the source S1, and the drain D1 may constitute a first transistor T1, and the first transistor T1 may be disposed in a platform isolation region MI1 to be isolated from other elements (not shown, e.g., elements such as additional transistors) disposed on the substrate 300. In some embodiments, the platform isolation region MI1 may refer to a platform formed by the first semiconductor layer 310, the second semiconductor layer 320, and/or the passivation layer 329, which are surrounded by grooves (not marked) disposed in the first semiconductor layer 310, the second semiconductor layer 320, and/or the passivation layer 329, on the substrate 300.

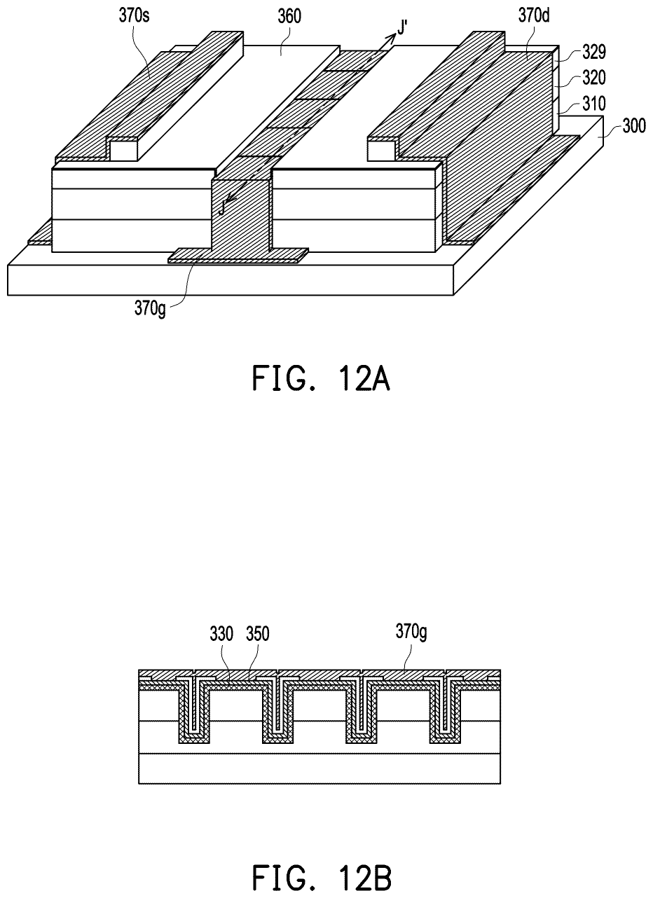

In some embodiments, the semiconductor structure 30 (or the first transistor T1) may further include a source pad, a gate pad, and a drain pad (not shown, referring to FIG. 12A for an example), which are electrically connected to the source S1, the gate G1, and the drain D1 respectively to serve as pads for the external connection of the source S1, the gate G1, and the drain D1.

It is worth noting that since the third semiconductor layer 330 is disposed on the second semiconductor layer 320, and the third semiconductor layer 330 may be in direct contact with the second semiconductor layer 320, a bandgap between the corresponding first semiconductor layer 310 and second semiconductor layer 320 is increased, raising the conduction band above the Fermi level, which causes the two-dimensional electron gas channels CH1 to remain in the depletion state without applying the bias voltage to the gates G1. If the two-dimensional electron gas channels CH1 are about to be turned on, a threshold voltage of the gates G1 is required to be increased accordingly to enable the two-dimensional electron gas to pass through the two-dimensional electron gas channels CH1. That is to say, by disposing the third semiconductor layer 330 between the gates G1 (or the first conductive layer 350) and the second semiconductor layer 320, the threshold voltage of the gates G1 may be increased, so that the first transistor T1 may be easily implemented as an enhanced high electron mobility transistor. In this embodiment, when a width L3 of the two-dimensional electron gas channels CH1 (or a width of the fin structures F1) is greater than 100 nm, the first transistor T1 may be implemented as the enhanced high electron mobility transistor, and the occurrence of the short-channel effect may be reduced.

In other embodiments, the third semiconductor layer 330 may not be disposed between the first conductive layer 350 and the second semiconductor layer 320. That is, the first conductive layer 350 is in direct contact with the second semiconductor layer 320. In this way, the depletion-type high electron mobility transistor may be easily formed. As a result, a type of the high electron mobility transistor may be adjusted by disposing the third semiconductor layer 330 or not disposing the third semiconductor layer 330 between the gates G1 (or the first conductive layer 350) and the fin structures F1.

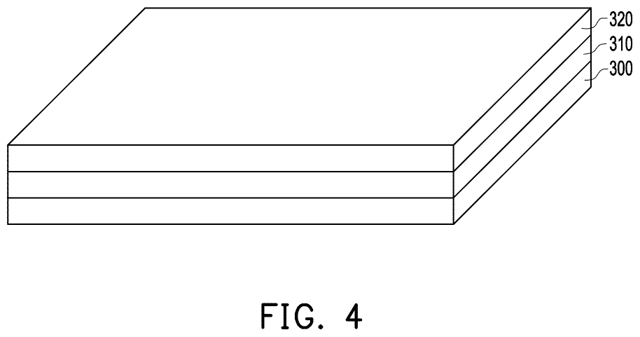

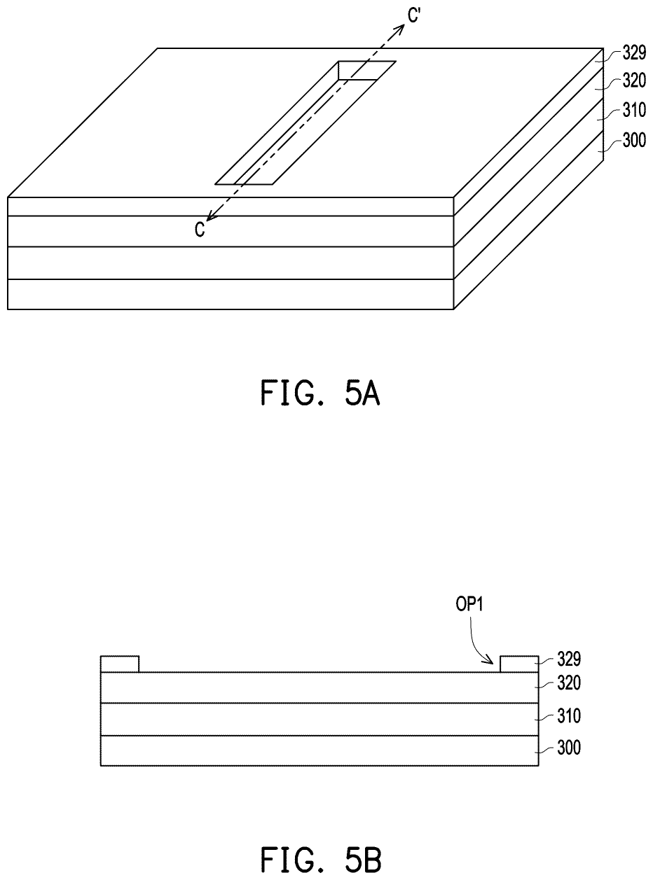

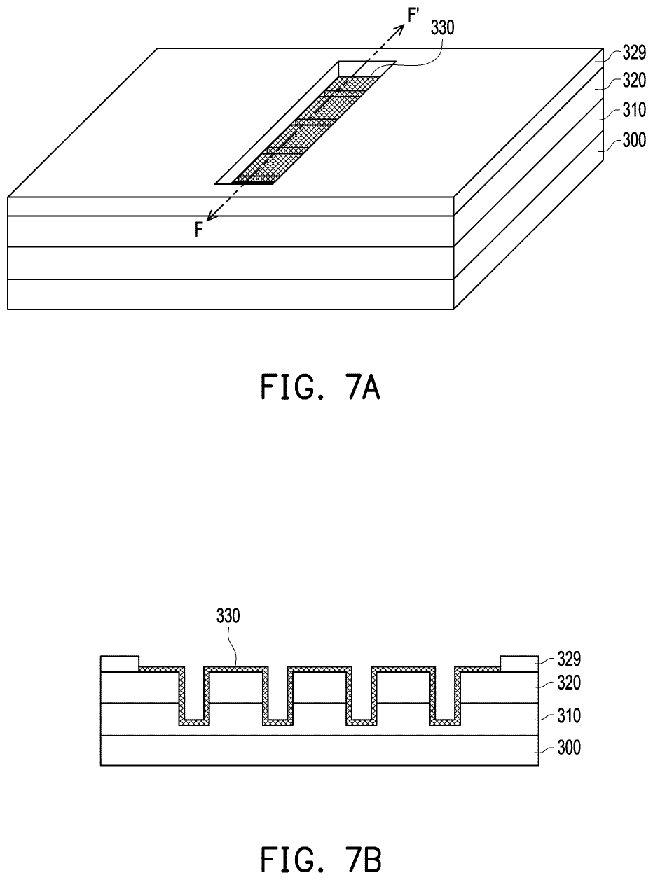

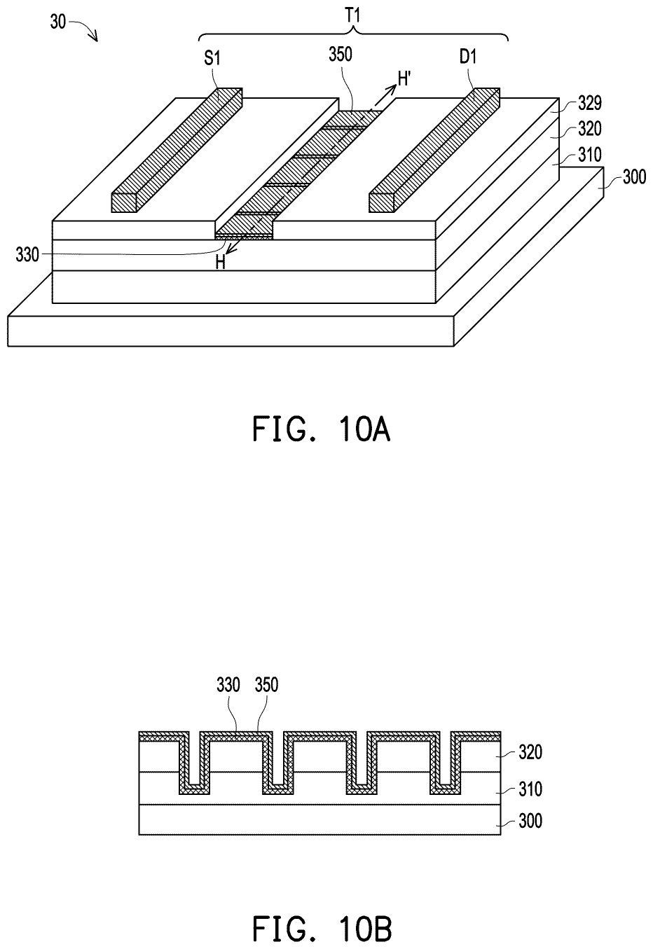

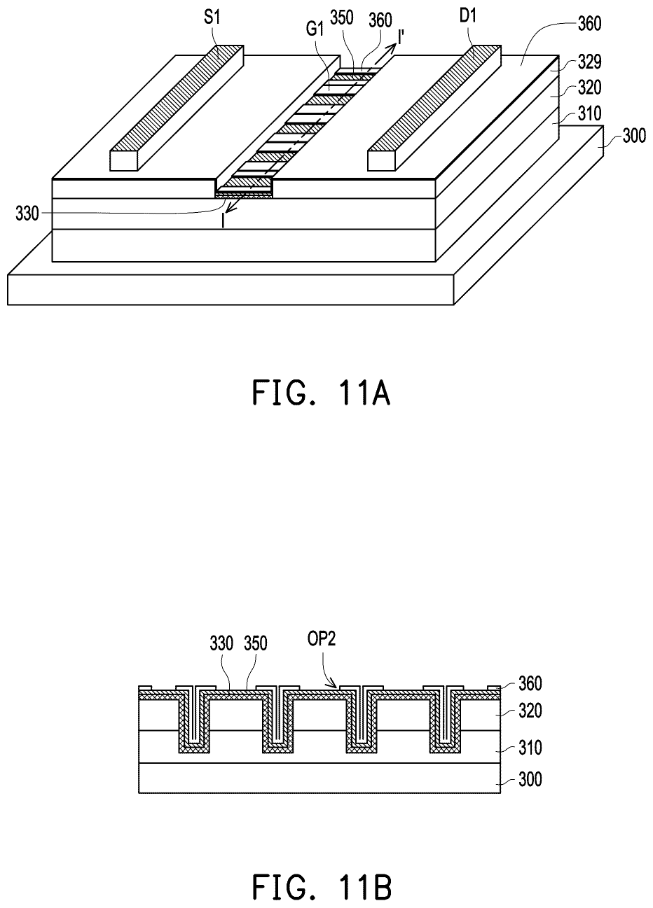

FIGS. 4, 5A, 6A, 7A, 8, 9, 10A, and 11A to 12A are schematic three-dimensional diagrams of a manufacturing process of the semiconductor structure 30 according to an embodiment of the disclosure. FIG. 5B is a schematic cross-sectional diagram of an embodiment cut along a sectional line C-C′ in FIG. 5A. FIG. 6B is a schematic cross-sectional diagram of an embodiment cut along a sectional line E-E′ in FIG. 6A. FIG. 7B is a schematic cross-sectional diagram of an embodiment cut along a sectional line F-F′ in FIG. 7A. FIG. 10B is a schematic cross-sectional diagram of an embodiment cut along a sectional line H-H′ in FIG. 10A. FIG. 11B is a schematic cross-sectional diagram of an embodiment cut along a sectional line I-I′ in FIG. 11A. FIG. 12B is a schematic cross-sectional diagram of an embodiment cut along a sectional line J-J′ in FIG. 12A. It is noted that some of the reference numerals and descriptions in FIGS. 3A and 3B will apply to FIGS. 4, 5A and 5B, 6A and 6B, 7A and 7B, 8, 9, 10A and 10B, 11A and 11B to 12A and 12B. The same reference numerals will represent the same or similar components and the descriptions of the same technical contents will be omitted. Reference may be made to the above embodiment for the omitted descriptions, which will not be repeated in the following embodiment.

Referring to FIG. 4, in this embodiment, the first semiconductor layer 310 is formed on the substrate 300, and the second semiconductor layer 320 is formed on the first semiconductor layer 310. The first semiconductor layer 310 and the second semiconductor layer 320 may be formed through the epitaxial process or other suitable growth processes, and the disclosure is not limited thereto.

Continuing from the manufacturing process in FIG. 4, referring to FIGS. 5A and 5B, the passivation layer 329 may be formed on the second semiconductor layer 320. For example, a passivation material layer (not shown) may be first formed on the second semiconductor layer 320 through chemical vapor deposition, physical vapor deposition, or other suitable deposition processes, and then the passivation material layer may be patterned to form the passivation layer 329. The passivation layer 329 has the opening OP1, which exposes a portion of the second semiconductor layer 320 to define a region where the gates G1 is to be formed subsequently.

Continuing from the manufacturing process in FIGS. 5A and 5B, referring to FIGS. 6A and 6B, the grooves R1 are formed in the second semiconductor layer 320 and the first semiconductor layer 310, thereby forming the fin structures F1. For example, a portion of the second semiconductor layer 320 and the first semiconductor layer 310 may be removed through a photolithography and etching process to form the grooves R1 that penetrates through the second semiconductor layer 320 and extends to a portion of the first semiconductor layer 310, and the unremoved second semiconductor layer 320 and first semiconductor layer 310 between the adjacent grooves R1 may constitute the fin structures F1.

Continuing from the manufacturing process in FIGS. 6A and 6B, referring to FIGS. 7A and 7B, the third semiconductor layer 330 is formed on the fin structures F1 and above the grooves R1, which means that the third semiconductor layer 330 covers the fin structures F1 and surfaces of the grooves R1. For example, the third semiconductor layer 330 may be conformally formed on the fin structures F1 and in the grooves R1 through the epitaxial growth process or other suitable processes.

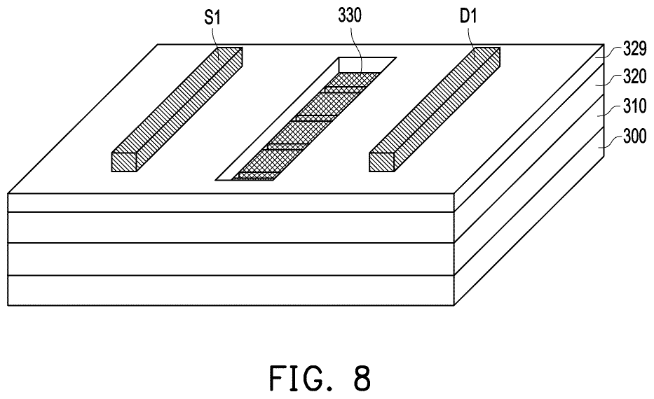

Continuing from the manufacturing process in FIGS. 7A and 7B, referring to FIG. 8, the source S1 and the drain D1 are formed on the second semiconductor layer 320. For example, an opening (not shown) may be first formed in the passivation layer 329 to expose a portion of the second semiconductor layer 320. Then, a conductive material layer is formed on the passivation layer 329 and in the above opening and patterned to form the source S1 and the drain D1.

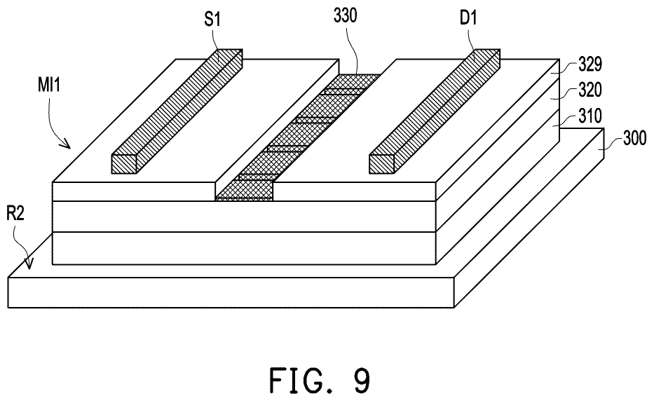

Continuing from the manufacturing process in FIG. 8, referring to FIG. 9, the platform isolation region MI1 is formed on the substrate 300, so that the element to be formed (i.e., the first transistor T1 in FIG. 10A) is located therein and isolated from other elements. For example, the patterned mask layer (e.g., photoresist, a hard mask, or a combination thereof) may be first formed on the passivation layer 329 to define a position of the platform isolation region MI1, and then a portion of the passivation layer 329, the second semiconductor layer 320 and the first semiconductor layer 310 are removed through an etching process to form a groove R2. The passivation layer 329, the second semiconductor layer 320 and the first semiconductor layer 310 which are surrounded by the groove R2, may constitute the platform isolation region MI1.

In some embodiments, the groove R2 surrounds the platform isolation region MI1. In some embodiments, the groove R2 may extend through the passivation layer 329, the second semiconductor layer 320 and the first semiconductor layer 310 to expose the substrate 300, but the disclosure is not limited thereto. In other embodiments, the groove R2 may extend through the passivation layer 329, the second semiconductor layer 320 and a portion of the first semiconductor layer 310, so that a portion of the first semiconductor layer 310 is exposed without exposing the substrate 300.

Continuing from the manufacturing process in FIG. 9, referring to FIGS. 10A and 10B, the first conductive layer 350 is formed on the third semiconductor layer 330. For example, the patterned mask layer (e.g., a photoresist layer) may be first formed on the passivation layer 329 to expose the third semiconductor layer 330, and then the first conductive layer 350 is formed on the third semiconductor layer 330 through the chemical vapor deposition, the physical vapor deposition, or other suitable deposition processes.

Based on the above manufacturing process, the manufacturing of the semiconductor structure 30 may be roughly completed.

In some embodiments, the manufacturing process in FIGS. 11A and 11B may be further continued with FIGS. 10A and 10B. As shown in FIGS. 11A and 11B, in the semiconductor structure 30, another passivation layer 360 may be further formed on the passivation layer 329 and cover a portion of the first conductive layer 350, a sidewall of the source S1 and a sidewall of drain D1. The passivation layer 360 may have multiple openings OP2 to expose a portion of the first conductive layer 350 (e.g., the gates G1), a top surface of the source S1, and a top surface of the drain D1.

In some embodiments, the manufacturing process in FIGS. 12A and 12B may be further continued with FIGS. 11A and 11B. As shown in FIGS. 12A and 12B, the semiconductor structure 30 may also further a source pad 370s, a gate pad 370g, and a drain pad 370d respectively on the source S1, the gate G1, and the drain D1. The source pad 370s, the gate pad 370g, and the drain pad 370d may respectively extend from the platform isolation region MI1 to a surface of the substrate 300, but the disclosure is not limited thereto.

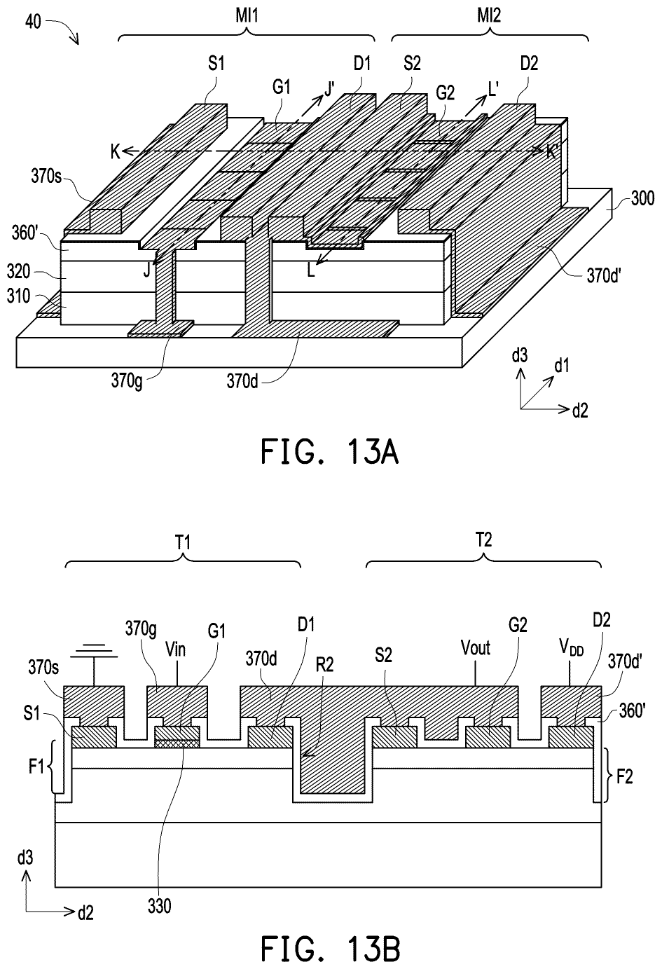

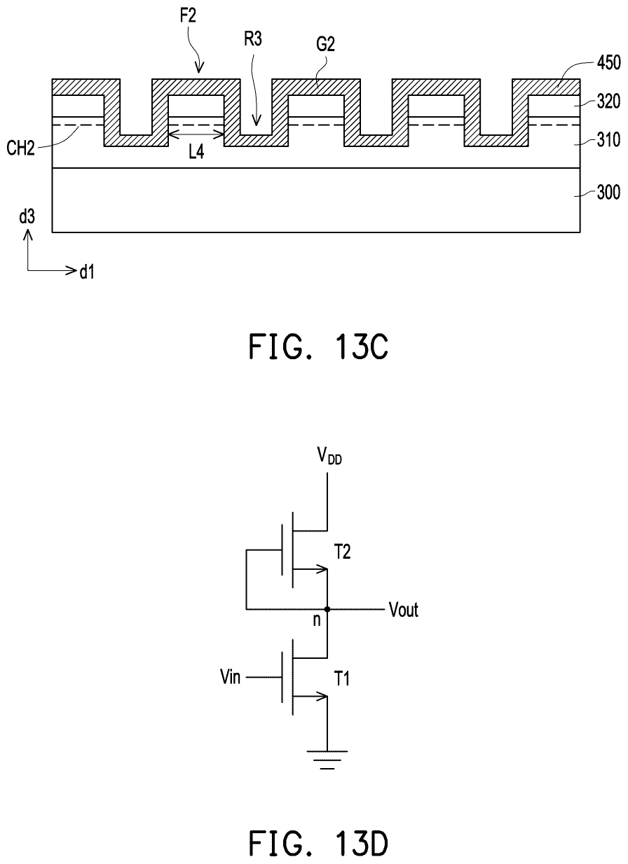

FIG. 13A is a schematic three-dimensional diagram of a semiconductor structure according to an embodiment of the disclosure. FIG. 13B is a schematic cross-sectional diagram of an embodiment cut along a sectional line K-K′ in FIG. 13A. FIG. 13C is a schematic cross-sectional diagram of an embodiment cut along a sectional line L-L′ in FIG. 13A. FIG. 13D is a schematic circuit diagram of a semiconductor structure according to an embodiment of the disclosure. For a schematic cross-sectional view cut along the sectional line J-J′ in FIG. 13A, reference may be made to FIG. 12B. It is noted that some of the reference numerals and descriptions in FIGS. 3A and 3B will apply to FIGS. 13A to 13D. The same reference numerals will represent the same or similar components and the descriptions of the same technical contents will be omitted. Reference may be made to the above embodiment for the omitted descriptions, which will not be repeated in the following embodiment. For ease of description, only one passivation layer 360′ is shown in FIGS. 13A and 13B, and components such as the passivation layer 360′ and a second conductive layer 450 are omitted in FIG. 13C. The passivation layer 360′ is equivalent to a combination of the passivation layer 329 and the passivation layer 360.

Referring to FIGS. 13A to 13C, it is worth noting that a semiconductor structure 40 in this embodiment is different from the semiconductor structure 30 in FIGS. 3A and 3B in that the semiconductor structure 40 may include the first transistor T1 and a second transistor T2 disposed on the substrate 300. In some embodiments, the first transistor T1 may be the enhanced high electron mobility transistor, and the second transistor T2 may be the depletion-type high electron mobility transistor. However, the disclosure is not limited thereto.

In some embodiments, the first transistor T1 may be located in the platform isolation region MI1, and the second transistor T2 may be located in a platform isolation region MI2. The platform isolation region MI2 and the platform isolation region MI1 may be arranged side by side on the substrate 300, and the platform isolation region MI2 and the platform isolation region MI1 are separated through the groove R2. The first transistor T1 may be similar to the first transistor T1 in FIGS. 12A and 12B.

In some embodiments, the second transistor T2 may include multiple fin structures F2, the second conductive layer 450 (or a gate G2, also called a second gate), the source S2 (also called a second source), and the drain D2 (also called a second drain). The gate G2 is disposed on the fin structures F2. The source S2 and the drain D2 are disposed on two opposite sides of the gates G2 respectively, so that the second conductive layer 450 is located between the source S2 and the drain D2. The second conductive layer 450, the source S2, and the drain D2 are arranged in parallel.

Each of the fin structures F2 includes the first semiconductor layer 310 and the second semiconductor layer 320. The second semiconductor layer 320 is disposed on the first semiconductor layer 310. The fin structures F2 are similar to the fin structures F1, and thus the same details will not be repeated in the following. The fin structures F2 are arranged on the substrate 300 in the first direction d1, and are separated from the fin structures F1 in the second direction d2. In some embodiments, the fin structures F2 (e.g., third fin structures) may be aligned with the fin structures F1 (e.g., the first fin structures) in second direction d2. In some embodiments, the second direction d2 may be perpendicular to the first direction d1 and the third direction d3.

From another perspective, multiple grooves R3 may be formed in the first semiconductor layer 310 and the second semiconductor layer 320 of the platform isolation region MI2, thereby forming the fin structures F2. Bottom surfaces of the grooves R3 is lower than the interface between the first semiconductor layer 310 and the second semiconductor layer 320, so that any two adjacent of the fin structures F2 are separated.

In some embodiments, the second conductive layer 450 may be conformally disposed on a top surface and sidewalls of the fin structures F2 and be in direct contact with the second semiconductor layer 320 and the first semiconductor layer 310. The first conductive layer 350 of the first transistor T1 is electrically isolated from the second conductive layer 450 of the second transistor T2.

The second conductive layer 450 may include the gates G2, and the gates G2 are located on the fin structure F2 and in direct contact with the second semiconductor layer 320. In some embodiments, the second conductive layer 450 may further extend into the groove R3 to electrically connect the adjacent gates G2, so that the gates G2 may be controlled by the same electrode.

Two-dimensional electron gas channels CH2 may be formed in the first semiconductor layer 310 of the fin structures F2, and are located near the interface between the first semiconductor layer 310 and the second semiconductor layer 320. In some embodiments, a width L4 of the two-dimensional electron gas channels CH2 (or a width of the fin structures F2) may be greater than 100 nm, so that the second transistor T2 is implemented as the depletion-type high electron mobility transistor.

In some embodiments, the drain D1 of the first transistor T1 is between the gate G1 of the first transistor T1 and the source S2 of the second transistor T2, and the source S2 of the second transistor T2 is between the drain D1 of the first transistor T1 and the gate G2 of the second transistor T2.

In some embodiments, the semiconductor structure 40 may be an inverter formed by the first transistor T1 and the second transistor T2, and a circuit diagram thereof is shown in FIG. 13D. The source S1 of the first transistor T1 may be grounded. The gate G1 of the first transistor T1 receives a voltage Vin. The drain D1 of the first transistor T1 is electrically connected to the source S2 of the second transistor T2. There is a node n between the drain D1 of the first transistor T1 and the source S2 of the second transistor T2, and the node n outputs a voltage Vout. The drain D2 of the second transistor T2 is electrically connected to a high voltage source VDD, and the gate G2 of the second transistor T2 is electrically connected to the node n.

In some embodiments, the drain pad 370d of the first transistor T1 may extend from the drain D1 of the first transistor T1 to the groove R2 between the platform isolation region MI1 and the platform isolation region MI2, and then extend to the source S2 and the gate G2 of the second transistor T2, so that the drain D1 of the first transistor T1 and the source S2 of the second transistor T2 are electrically connected to the gate G2.

In some embodiments, the second transistor T2 may further include a drain pad 370d′, which is disposed on the drain D2 of the second transistor T2 and extends out of the platform isolation region MI2 to serve as a pad for external connection.

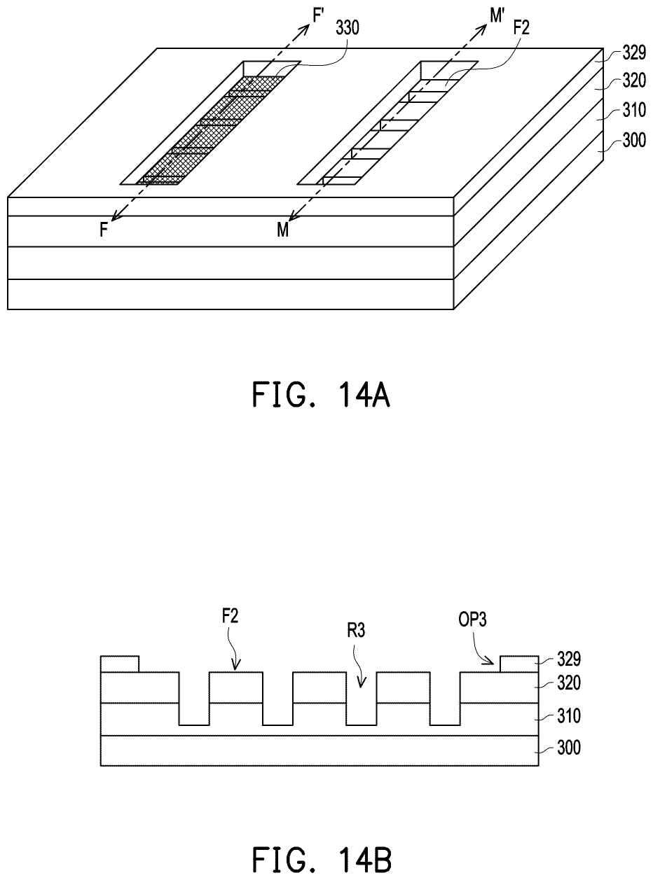

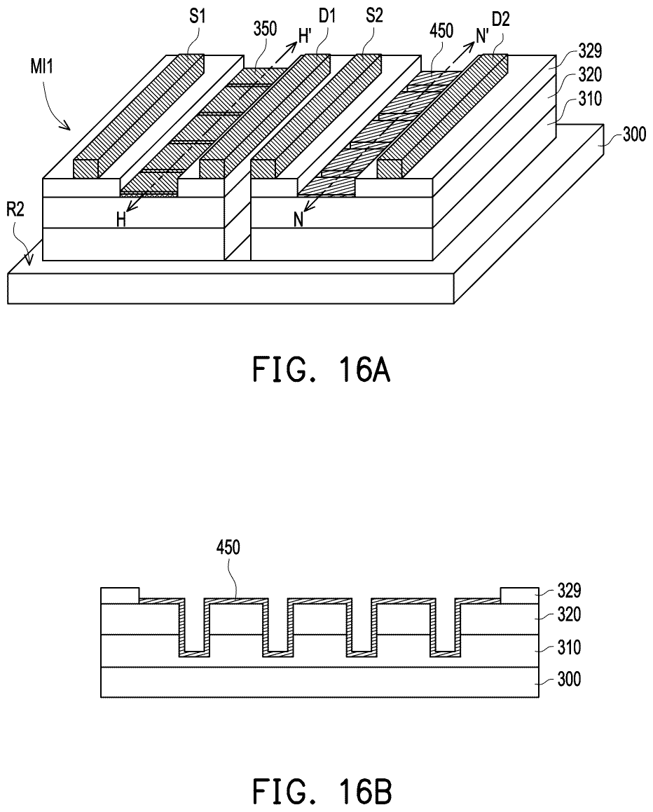

FIGS. 14A, 15, and 16A are schematic three-dimensional diagrams of a manufacturing process of a semiconductor structure according to an embodiment of the disclosure. FIG. 14B is a schematic cross-sectional view of an embodiment cut along a sectional line M-M′ in FIG. 14A. FIG. 16B is a schematic cross-sectional view of an embodiment cut along a sectional line N-N′ in FIG. 16A. For a schematic cross-sectional view cut along the sectional line F-F′ in FIG. 14A, reference may be made to FIG. 7B. For a schematic cross-sectional view cut along the sectional line H-H′ in FIG. 16A, reference may be made to FIG. 10B. It is noted that some of the reference numerals and descriptions in FIGS. 13A and 13B will apply to FIGS. 14A and 14B, 15, and 16A and 16B. The same reference numerals will represent the same or similar components and the descriptions of the same technical contents will be omitted. Reference may be made to the above embodiment for the omitted descriptions, which will not be repeated in the following embodiment.

Referring to FIGS. 14A and 14B, FIG. 14A may be a continuation of the manufacturing process in FIGS. 4 to 7A, and then an opening OP3 is formed in the passivation layer 329 to define a region where the gate G2 is to be formed subsequently, which is similar to the process in FIGS. 5A and 5B. After that, the grooves R3 are formed in the second semiconductor layer 320 and the first semiconductor layer 310, thereby forming the fin structures F2, which is similar to the process in FIGS. 6A and 6B.

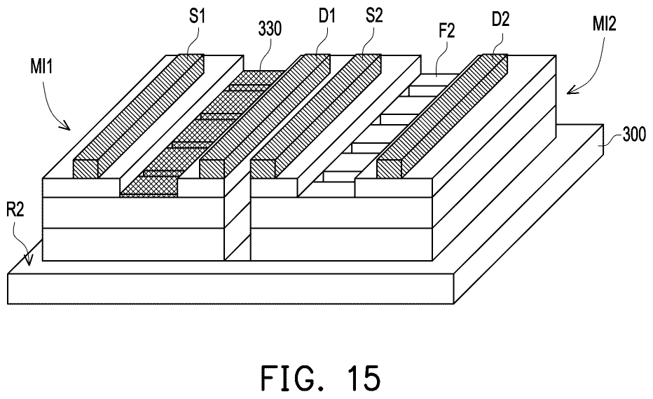

Referring to FIG. 15, the sources S1 and S2 and the drains D1 and D2 are formed on the second semiconductor layer 320, which is similar to the process in FIG. 8. The source S1 and the drain D1 are located on two sides of the fin structures F1, and the source S2 and the drain D2 are located on two sides of the fin structures F2. Then, the platform isolation regions MI1 and MI2 are formed, so that the elements to be formed (i.e., the first transistor T1 and the second transistor T2) are respectively located therein and isolated from other elements, which is similar to the process in FIG. 9.

Referring to FIGS. 16A and 16B, the first conductive layer 350 is formed on the third semiconductor layer 330, and the second conductive layer 450 is formed in the fin structures F2 and the grooves R3, which may be manufactured by a method similar to that in FIGS. 10A and 10B. The first conductive layer 350 and the second conductive layer 450 may be formed in the same process step.

After that, referring to FIG. 13A, the source pad 370s may be formed on the source S1, the gate pad 370g may be formed on the gate G1, the drain pad 370d may be formed on the drain D1, the source S2, and the gate G2, and the drain pad 370d′ may be formed on the drain D2, which may be formed by the process similar to that in FIGS. 11A and 11B to 12A and 12B.

Based on the above, in the semiconductor structure of the disclosure, by disposing the third semiconductor structure and the insulating layer between the conductive layer and the second semiconductor layer to isolate the adjacent two-dimensional electronic channels, the process may be simplified, and the enhanced or depletion-type high electron mobility transistor may be flexibly implemented according to requirements. In addition, in the semiconductor structure of the disclosure, the enhanced or depletion-type high electron mobility transistor may be formed by disposing or not disposing the third semiconductor layer between the gate and the fin structure, thereby simplifying the process and thus reducing manufacturing costs.

What is claimed is:

1. A semiconductor structure, comprising:
a first semiconductor layer dispsoed over a substrate;
a second semiconductor layer disposed on the first semiconductor layer;
a plurality of third semiconductor structures disposed on the second semiconductor layer;
a conductive layer disposed on the third structure semiconductors; and
an insulating layer disposed between the conductive layer and the third semiconductor structures to electrically isolate the conductive layer from the third semiconductor structures,
wherein a two-dimensional electron gas channel is formed in a portion of the first semiconductor layer, the portion of the first semiconductor layer is not overlapped with the third semiconductor structures in a vertical direction, and the two-dimensional electron gas channel is located near an interface between the first semiconductor layer and the second semiconductor layer, wherein the vertical direction is parallel to a normal direction of a top surface of the substrate.

2. The semiconductor structure according to claim 1, wherein the conductive layer further extends onto the second semiconductor layer, and the conductive layer is in direct contact with the second semiconductor layer.

3. The semiconductor structure according to claim 1, further comprising:
a plurality of fourth semiconductor structures disposed on the second semiconductor layer, wherein the fourth semiconductor structures are arranged with the third semiconductor structures in a staggered manner, so that one of the third semiconductor structures is arranged between two adjacent ones of the fourth semiconductor structures, and one of the fourth semiconductor structures is arranged between two adjacent ones of the third semiconductor structures.

4. The semiconductor structure according to claim 3, wherein the two-dimensional electron gas channel is overlapped with the fourth semiconductor structures in the vertical direction.

5. The semiconductor structure according to claim 3, wherein the conductive layer is further disposed on the fourth semiconductor structures and is in direct contact with the fourth semiconductor structures.

6. The semiconductor structure according to claim 3, wherein the third semiconductor structures and the fourth semiconductor structures comprise p-type gallium nitride.

7. The semiconductor structure according to claim 3, wherein the insulating layer is located between the third semiconductor structures and the fourth semiconductor structures that are adjacent.

8. The semiconductor structure according to claim 3, wherein a distance between the adjacent third semiconductor structures is greater than 100 nm.

9. A semiconductor structure, comprising:
a first transistor, comprising:
a first fin structure disposed over a substrate, wherein the first fin structure comprises:
a first semiconductor layer; and
a second semiconductor layer disposed on the first semiconductor layer, wherein a sidewall of the first semiconductor layer is flush with a sidewall of the second semiconductor layer;
a third semiconductor layer disposed on a top surface and a sidewall of the first fin structure; and
a first gate disposed on the third semiconductor layer,
wherein a two-dimensional electron gas channel is formed in the first semiconductor layer of the first fin structure and is located near an interface between the first semiconductor layer and the second semiconductor layer.

10. The semiconductor structure according to claim 9, wherein the third semiconductor layer is in direct contact with the first semiconductor layer.

11. The semiconductor structure according to claim 9, wherein the first transistor further comprises a second fin structure, and the first fin structure and the second fin structure are arranged in a first direction, wherein the first semiconductor layer of the first fin structure extends to the second fin structure, and there is a first groove between the first fin structure and the second fin structure, wherein the first direction is parallel to a top surface of the substrate.

12. The semiconductor structure according to claim 11, wherein the third semiconductor layer further extends from the first fin structure to the first groove and a top surface and a sidewall of the second fin structure.

13. The semiconductor structure according to claim 11, wherein a bottom surface of the first groove is lower than the interface between the first semiconductor layer and the second semiconductor layer.

14. The semiconductor structure according to claim 11, further comprising a second transistor, wherein the second transistor comprises:
a third fin structure disposed on the substrate, wherein the third fin structure and the first fin structure are arranged in a second direction, and the second direction is perpendicular to the first direction and parallel to the top surface of the substrate; and
a second gate disposed on a top surface and a sidewall of the third fin structure.

15. The semiconductor structure according to claim 14, wherein the second gate is in direct contact with the third fin structure.

16. The semiconductor structure according to claim 14, wherein the first transistor further comprises:
a first source and a first drain dispsoed on two sides of the first gate in the second direction,
wherein the second transistor further comprises:
a second source and a second drain dispsoed on two sides of the second gate in the second direction,
wherein the first drain is located between the first gate and the second source, and the second source is located between the first drain and the second gate.

17. The semiconductor structure according to claim 16, further comprising:
a drain pad dispsoed on the first drain and extending to the second source and the second gate, so that the first drain, the second source, and the second gate are electrically connected.

18. The semiconductor structure according to claim 14, wherein the first transistor is an enhanced high electron mobility transistor, and the second transistor is a depletion-type high electron mobility transistor.

19. The semiconductor structure according to claim 9, wherein a width of the first fin structure is greater than 100 nm.

20. The semiconductor structure according to claim 9, wherein the first semiconductor layer comprises gallium nitride, the second semiconductor layer comprises aluminum gallium nitride, and the third semiconductor layer comprises p-type gallium nitride.
